(19) United States
(12) Patent Application Publication
(10) Pub. No.: US 2025/0299727 A1
(43) Pub. Date: Sep. 25, 2025

(54) STATIC RANDOM-ACCESS MEMORY

(71) Applicant: Intel Corporation, Santa Clara, CA (US)

(72) Inventors: Charles AUGUSTINE, Portland, OR (US); Amlan GHOSH, Mebane, NC (US); Martin OSTERMAYR, Woerth (DE); Patrick MORROW, Portland, OR (US); Seenivasan SUBRAMANIAM, Hillsboro, OR (US); Muhammad M. KHELLAH, Tigard, OR (US); Feroze MERCHANT, Austin, TX (US)

(21) Appl. No.: 19/059,871

(22) Filed: Feb. 21, 2025

Related U.S. Application Data
(63) Continuation of application No. PCT/US2024/021233, filed on Mar. 22, 2024.

(51) Int. Cl. G11C 11/412; G11C 11/419; H10B 10/00; H10D 84/85

(52) U.S. Cl. CPC G11C 11/412; G11C 11/419; H10B 10/12; H10D 84/85

(57) ABSTRACT

Embodiments herein relate to a memory cell having n-type metal-oxide-semiconductor field-effect transistor (nMOSFETs) in one layer in the cell and pMOSFET transistors in another, lower layer of the cell, and one or more intermediate metal (IM) layers between the nMOS and pMOS transistors. The IM layers can provide routing between the nMOS and pMOS transistors, to one or more top metal layers, above the nMOS transistors, and to one or more bottom metal layers, below the pMOS transistors. An example six-transistor cell can include four nMOS transistors and two pMOS transistors, and an example eight-transistor cell can include four nMOS transistors and four pMOS transistors.

### CROSS-REFERENCE TO RELATED APPLICATIONS

This application is a continuation application of International Application PCT/US2024/021233, filed Mar. 22, 2024, entitled “STATIC RANDOM-ACCESS MEMORY,” and incorporated herein by reference.

### FIELD

The present application generally relates to the field of memory devices and more particularly, to a static random-access memory (SRAM).

### BACKGROUND

Memory devices include both volatile and non-volatile memory. The demand for memories has increased as larger on-die caches are employed such as in high-performance processors. This demand is further amplified due to the integration of accelerators such as Tile Matrix Multiply (TMUL) units, Advanced Vector Extensions (AVX) and Vision Processing Units (VPU) to support new workloads. Static Random-Access Memory (SRAM) is a default candidate for supporting these workloads and providing on-chip high density memory. However, SRAM faces scalability issues due to lithography challenges associated with process scaling.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts plots of normalized density versus technology node for logic density (plot 100) and Static Random-Access Memory (SRAM) cell density (plot 101), in accordance with various embodiments.

FIG. 2 depicts a perspective view of a comparative complementary field-effect transistor (CFET) device 200, in accordance with various embodiments.

FIG. 3 depicts a perspective view of a CFET device 300 with intermediate metal layers IM0 and IM1, in accordance with various embodiments.

FIG. 4 depicts an example circuit diagram of a six-transistor (6T) SRAM memory cell 400, in accordance with various embodiments.

FIG. 5 depicts an example plan view of a comparative SRAM cell 500 without CFET technology, consistent with FIG. 4, in accordance with various embodiments.

FIG. 6A depicts an example plan view of a front side (FS) 600 of an SRAM cell which uses CFET technology but not intermediate metal layers, consistent with FIG. 4, in accordance with various embodiments.

FIG. 6B depicts an example plan view of a back side (BS) 660 of the SRAM cell of FIG. 6A in accordance with various embodiments.

FIG. 6C depicts an example plan view of a front side metal 0 (M0) layer and a back side base metal 0 (BM0) layer of the SRAM cell of FIG. 6A, in accordance with various embodiments.

FIG. 7A depicts an example plan view of a front side 700 of a 6T SRAM cell which uses CFET technology and intermediate metal layers, consistent with FIG. 4, in accordance with various embodiments.

FIG. 7B depicts an example plan view of an intermediate layer 750 of the SRAM cell of FIG. 7A, including intermediate metal layer IM0, in accordance with various embodiments.

FIG. 7C depicts an example plan view of a back side 760 of the SRAM cell of FIG. 7A in accordance with various embodiments.

FIG. 7D depicts an example plan view of a front side M0 layer of the SRAM cell of FIG. 7A, in accordance with various embodiments.

FIG. 7E depicts an example plan view of a first intermediate metal layer (IM0) of the SRAM cell of FIG. 7A, in accordance with various embodiments.

FIG. 7F depicts an example plan view of a second intermediate metal layer (IM1) of the SRAM cell of FIG. 7A, in accordance with various embodiments.

FIG. 7G depicts an example plan view of a back side BM0 layer of the SRAM cell of FIG. 7A, in accordance with various embodiments.

FIG. 8A depicts an example circuit diagram of an eight-transistor (8T) SRAM memory cell 800, in accordance with various embodiments.

FIG. 8B depicts an example table of word line and bit line voltages for write, read and retention operations in the SRAM cell 800 of FIG. 8A, in accordance with various embodiments.

FIG. 9A depicts an example plan view of a front side 900 of an 8T SRAM cell which uses CFET technology but without intermediate metal layers, consistent with FIG. 8A, in accordance with various embodiments.

FIG. 9B depicts an example plan view of a back side 950 of the SRAM cell of FIG. 9A in accordance with various embodiments.

FIG. 9C depicts an example plan view of a front side M0 layer of the SRAM cell of FIG. 9A, in accordance with various embodiments.

FIG. 9D depicts an example plan view of a back side BM0 layer of the SRAM cell of FIG. 9A, in accordance with various embodiments.

FIG. 10A depicts an example plan view of a front side 1000 of an 8T SRAM cell which uses CFET technology and intermediate metal layers, consistent with FIG. 8A, in accordance with various embodiments.

FIG. 10B depicts an example plan view of a back side 1050 of the SRAM cell of FIG. 10A in accordance with various embodiments.

FIG. 10C depicts an example plan view of a front side M0 layer of the SRAM cell of FIG. 10A, in accordance with various embodiments.

FIG. 10D depicts an example plan view of a first intermediate metal layer (IM0) of the SRAM cell of FIG. 10A, in accordance with various embodiments.

FIG. 10E depicts an example plan view of a second intermediate metal layer (IM1) of the SRAM cell of FIG. 10A, in accordance with various embodiments.

FIG. 10F depicts an example plan view of a back side BM0 layer of the SRAM cell of FIG. 10A, in accordance with various embodiments.

FIG. 10G depicts an example of the intermediate IM0 layer of the SRAM cell of FIG. 10A, in accordance with various embodiments.

FIG. 11A depicts an example view of an n-type metal-oxide-semiconductor field-effect transistor (nMOSFET or nMOS) 1150 and p-type MOSFET (pMOS) 1160, in accordance with various embodiments.

FIG. 11B depicts an example perspective view of different layers and vias in an SRAM cell which uses CFET technology and intermediate metal layers, consistent with FIGS. 7A-7D and 10A-10F, in accordance with various embodiments.

FIG. 12 illustrates an example of components that may be present in a computing system 1250 for implementing the techniques (e.g., operations, processes, methods, and methodologies) described herein.

### DETAILED DESCRIPTION

Various challenges are presented in scaling semiconductor memory devices such as Static Random-Access Memory (SRAM).

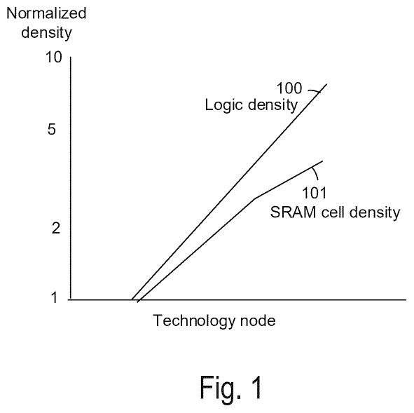

On-chip memories consume a large portion, e.g., about 30%, of the silicon die area. Going forward, the percentage of on-chip memories is expected to increase dramatically with more accelerators being added to improve the performance and efficiency of the chips. For example, in some memory designs, the L2 cache capacity is doubled, e.g., from 1280 KB to 2048 K B. However, at the same time the scaling of SRAM has slowed down significantly from a baseline scaling of 2× between consecutive technology generations to 1.2× whereas the logic continues to scale at 2× between one technology node to the next (see FIG. 1). This results in more silicon area devoted to on-chip memory.

One solution involves using complementary field-effect transistor (CFET) technology in which p-type and n-type metal-oxide-semiconductor field-effect transistors (MOSFETs) can be vertically stacked, thus allowing 2× density scaling. However, in on-chip memories such as SRAM, the interconnect limits the memory density scaling and, as a result, scaling of SRAM becomes even more challenging. Moreover, the bit-cell scaling restricts the widths of metal tracks, increasing resistance and degrading the SRAM read and write performance.

The solutions provided herein address the above and other challenges.

In one aspect, a memory cell is provided which uses CFET technology, where nMOS transistors at one layer (level or height) in the cell are provided above pMOS transistors in another, lower layer of the cell, and one or more intermediate metal (IM) layers are provided between the nMOS and pMOS transistors. For example, a first IM layer (IM0) can providing routing in a first (x) direction, and a second IM layer (IM1) can providing routing in a second (y) direction which is perpendicular to the first direction.

In an example implementation, the one or more intermediate metal layers comprise a first intermediate metal layer having tracks extending in a first direction (e.g., x-direction) and a second intermediate metal layers comprising tracks extending in a second direction (e.g., y-direction), perpendicular to the first direction.

The IM layers can provide routing between the nMOS and pMOS transistors in their different respective levels as well to one or more top metal layers, above the nMOS transistors, and to one or more bottom metal layers, below the pMOS transistors. The cell includes one or more back side (bottom) metal layers, e.g., BM0, BM1 . . . and one or more front side (top) metal layers, e.g., M0, M1 . . . .

In example implementations, the memory cell is a SRAM having six, eight, ten or other number of transistors.

For example, a six-transistor (6T) SRAM cell can include four nMOS transistors on the front side of the cell and two pMOS transistors on the back side of the cell. In another example, an eight-transistor (8T) SRAM cell can include four nMOS transistors on the front side of the cell and four pMOS transistors on the back side of the cell.

The memory cell has advantages including improved scaling and reduced resistance. The IM layers provide simplified interconnect routing which results in reduced area and increased read and write performance.

These and other features will be further apparent in view of the following discussion.

FIG. 1 depicts plots of normalized density versus technology node for logic density (plot 100) and Static Random-Access Memory (SRAM) cell density (plot 101), in accordance with various embodiments. As mentioned, logic density continues to increase in proportion to the technology node, which represents an increasingly smaller dimension along the horizontal axis. However, SRAM cell density has increased at a lower rate, resulting in a disparity between logic and SRAM scaling across technology generations. The techniques provided herein address this issue by improving SRAM cell density.

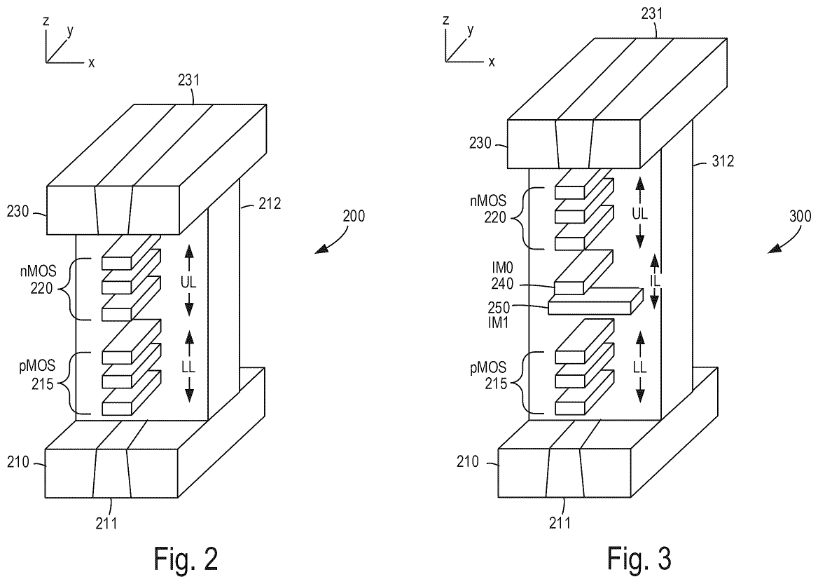

FIG. 2 depicts a perspective view of a comparative complementary field-effect transistor (CFET) device 200, in accordance with various embodiments. The CFET is a product of an evolution of transistor technology from Fin Field-Effect Transistor (FinFET) to nanosheet FET to CFET. CFET enables a 50% front end scaling with nMOS transistors stacked vertically on top of pMOS transistors. CFET technology provides vertical integration of pMOS and nNMOS transistors.

The device 200 include a substrate region 210 with a metal line 211 (part of a bottom metal layer) at the bottom and a region 230 with a metal line 231 (part of a top metal layer) at the top. An elevated region 212 includes a lower layer (LL), e.g., a pMOSFET layer 215 (a p-type transistor layer) with one or more pMOS transistors (pMOSFETs), below an upper layer (UL), e.g., an nMOSFET layer 220 (an n-type transistor layer) with one or more nMOS transistors (nMOSFETs). The nMOS transistor layer may overlay, at least in part, and have an overlapping footprint with, the pMOS transistor layer. The substrate extends in an x-y plane. In this example, each transistor includes three channels in the form of ribbons, where each channel is surrounded by a gate, as a gate-all-around transistor. The transistors can also be referred to as RibbonFETs. Three channels is an example, as 2-5 channels can be used, for example.

pMOS source and drain regions can be connected to nMOS source and drain regions through vias since they are on different layers, e.g., the nMOS layer on the top and the pMOS layer on the bottom.

The device 200 represents part of a memory cell which includes multiple pMOS transistors at a first, e.g., lower layer of the memory cell and multiple nMOS transistors at a second, e.g., upper layer of the memory cell.

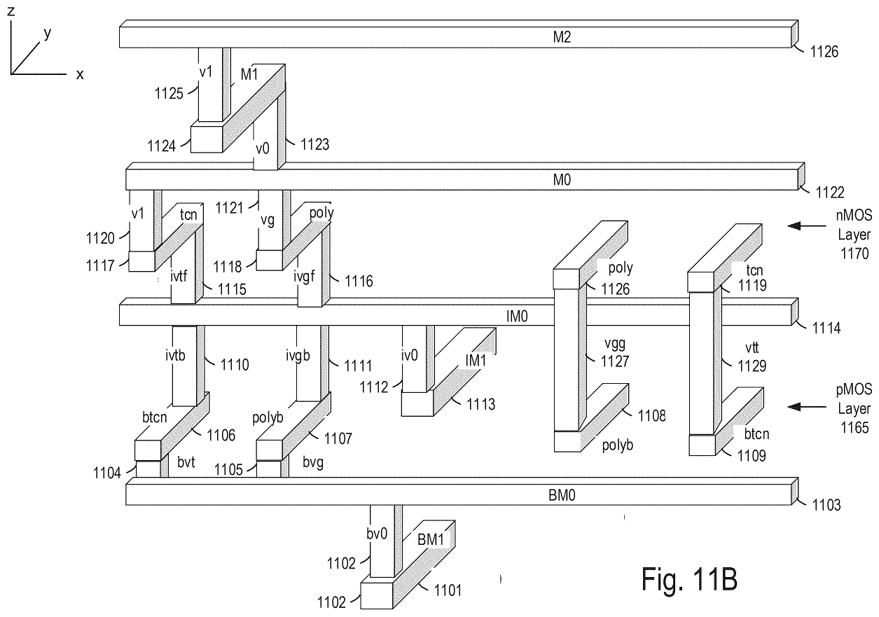

FIG. 3 depicts a perspective view of a CFET device 300 with intermediate metal layers IM0 and IM1, in accordance with various embodiments. The device includes like-numbered components of FIG. 2. Additionally, one or more IM layers are added in an intermediate level (IL) between the pMOS and nMOS layers in the elevated region 312. The IM layers help with routing signals to help further scale the circuit area. The IM layers include a first IM layer (IM0) 240 which provides routing in the y direction and a second IM layer (IM1) 250 which provides routing in the x direction, perpendicular to the y direction. The routing of the IM layer can be parallel to the surface of the substrate in the x-y plane. See also FIG. 11B, which provides example of how IM0 and IM1 can be used in routing voltages and signals. IM0 is above IM1 in this example. In another example, IM0 is below IM1.

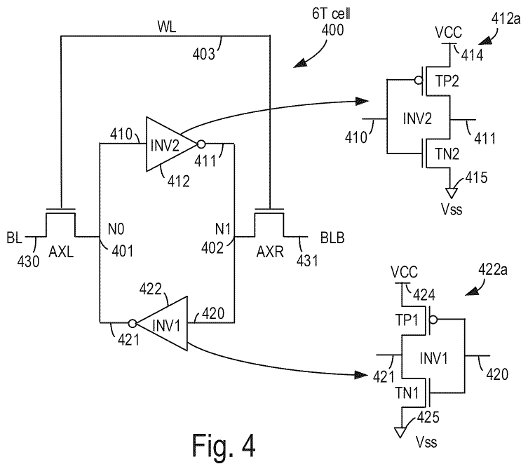

The solutions provided herein include adding IM or other conductive layers between the vertically stacked nMOS and pPMOS layers in a CFET device. The IM layers can help balance the distribution of metal tracks used in a memory cell at different layers of the cell. For example, the IM layers can balance the distribution of six metal tracks used for the six signals of a 6T SRAM cell (e.g., BL, BLB, N0, N1, VCC and VSS such as depicted in FIG. 4) between the one or more top metal layers (e.g., M0-M2, see FIG. 11B), one or more bottom metal layer (e.g., BM0 and BM1) and one or more IM layers (e.g., IM0 and IM1). In an example implementation of a SRAM cell without IM0 and IM1, a top metal layer such as M0 may carry five out of the six signals. This limits the maximum width of the metal layer portions which carry the signals. Metal wires with smaller widths have higher resistance, which is detrimental to the read and write performance of the cell. A similar advantage can be achieved for an 8T SRAM cell or other configurations.

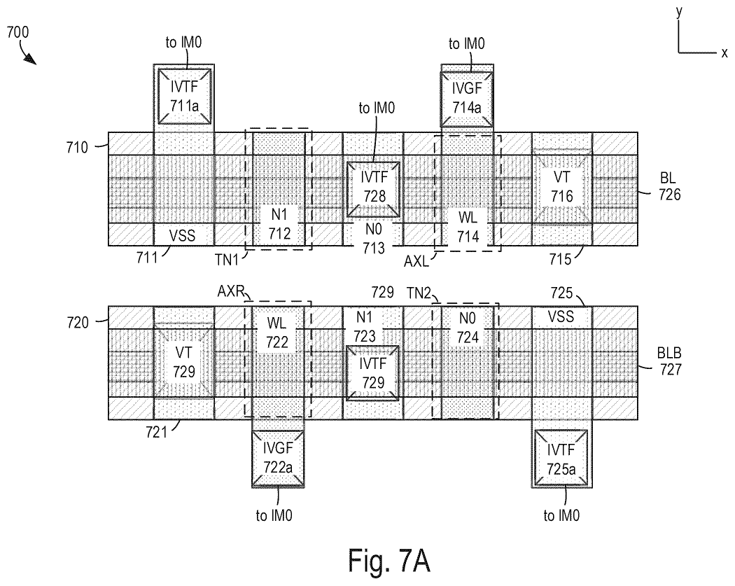

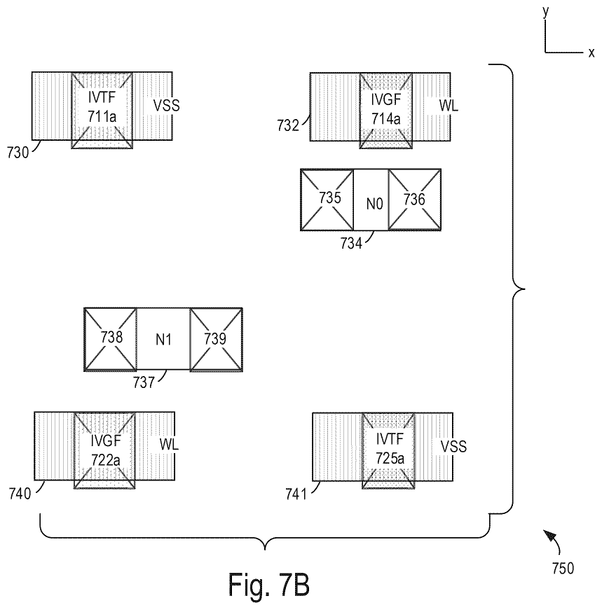

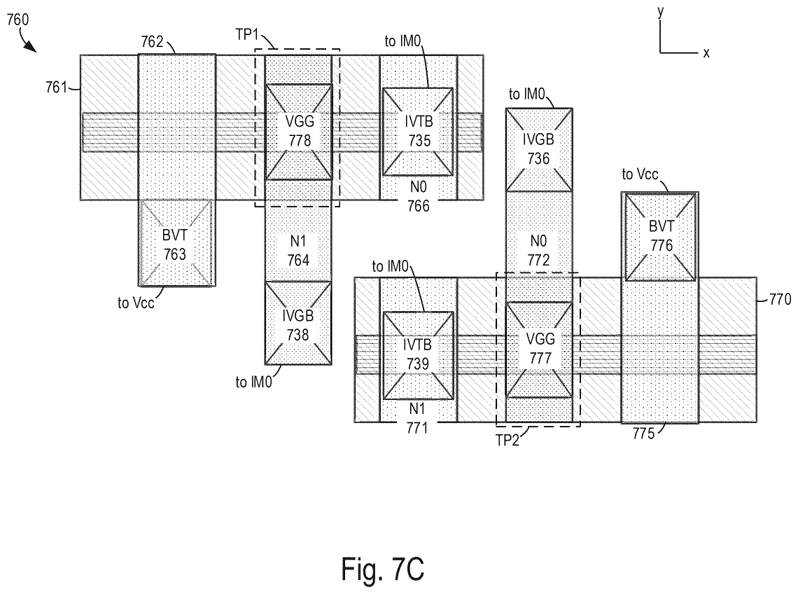

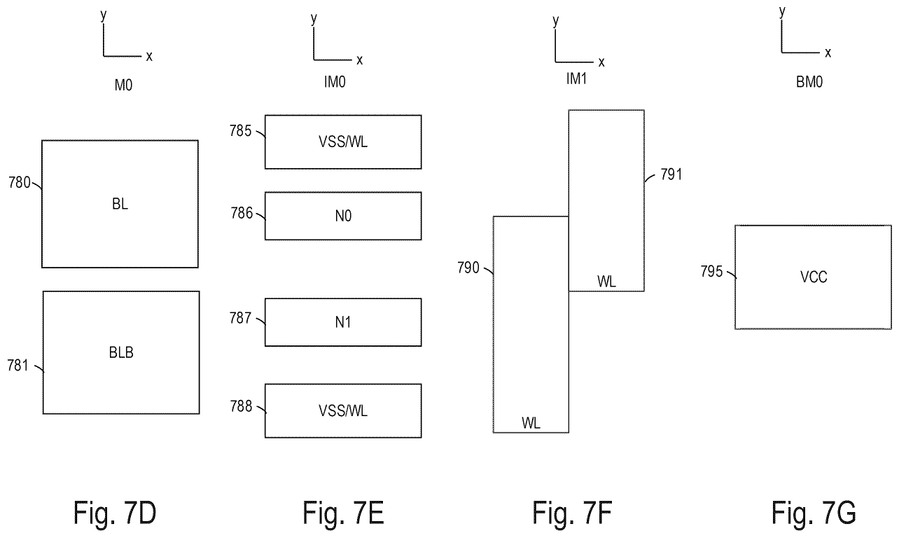

In an example implementation with IM0 and IM1, M0 can carry two tracks (e.g., elongated conductive paths or routes) for BL and BLB, IM0 can carry three tracks for N0, N1 and 2×0.5WL/0.5VSS (two half-tracks each for Vss and WL), and BM0 can carry one track for VCC. See FIGS. 7D-7G. This helps to maintain the cell height (in the y-direction) while increasing the width (y-direction) of BL/BL_B by about 30%, for example. This in turn reduces the BL/BLB resistance by about 24%. A similar solution can be used for a 2R-1 W (dual-read or a single-write operation) multi-port SRAM designs to improve the widths of RBL0/RBL1/WBL/WBLB, which also results in a similar resistance improvement as mentioned above.

Dense SRAM memory cells using complementary transistors can be used in a variety of applications such as a system-on-a-chip (SOc) where density, performance and power consumption are bottlenecks. Other example applications include those with multiple integrated circuits within the same package, e.g., stacked tile/chiplet designs and other system-in-a-package designs that include multiple chips.

The proposed SRAM memory cell implementations address the challenges of scaling and can be integrated with high density and high yield.

In some implementations, the memory cell can be implemented without the use of a GCN via layer a poly-to-diffusion gate contact). See, e.g., FIGS. 7A-7B. In some implementations, the memory cell can allow an increase in the widths (y direction) of BL/BLB to reduce their resistance, increasing the read and write performance. The memory cell can also allow for a decrease in the bit cell height (z direction).

In some implementation, IM layers are incorporated in a 2R-1 W SRAM cell to show the scalability with proposed intermediate layers in other bit-cell topologies resulting in a significant resistance improvement which would otherwise require an increase in the height of the multi-port SRAM cell.

FIG. 4 depicts an example circuit diagram of a six-transistor (6T) SRAM memory cell 400, in accordance with various embodiments. The cell includes first and second inverters INV1 422 and INV2 412, respectively, and first and second cross-coupled nodes N0 and N1, respectively. N0 401 can be coupled to a primary bit line BL 430 by a left-side nMOS access transistor AXL (a first access transistor), and N1 402 can be coupled to a complementary bit line BLB 431 by a right-side nMOS access transistor AXR (a second access transistor). The control gates of the access transistors are connected to a word line (WL) 403. Enabling the WL electrically connects BL to N0 and BLB to N1. N0 and N1 provide complementary bit values, where the bit value at node N0 is considered to be the value stored by the memory cell.

INV2 412 includes an input 410 coupled to N0 401 and an output 411 coupled to N1 402. A circuit 412a provides an example implementation of INV2 and includes a pMOS transistor TP2 in series with an nMOS transistor TN2. These transistors have their gates coupled to the input 410. The drain of TP2 and a drain of TN2 are coupled to each other and to the output 411. A source of TP2 is coupled to a power supply node 414 at a voltage Vcc. A source of TN2 is coupled to a ground node 415 at a voltage Vss such as 0 V.

INV1 422 includes an input 420 coupled to N1 402 and an output 421 coupled to N0 401. A circuit 422a provides an example implementation of INV1 and includes a pMOS transistor TP1 in series with an nMOS transistor TN1. These transistors have their gates coupled to the input 420. A drain of TP1 and a drain of TN1 are coupled to each other and to the output 421. A source of TP1 is coupled to a power supply node 424 at a voltage Vcc. A source of TN1 is coupled to a ground node 425 at a voltage Vss such as 0 V.

If the memory cell 400 is implemented using the CFET technology of FIG. 2, the two inverters (INV1 and INV2) can be scaled by 50%. However, the SRAM bit-cell area does not scale similarly due to non-scalability of the SRAM interconnect structures used for internal cross-couple connections N0 and N1 along with those used for connecting the bit cell to BL, BLB, and WL. A special via layer, GCN, can be introduced with the CFET process to scale the bit-cell area.

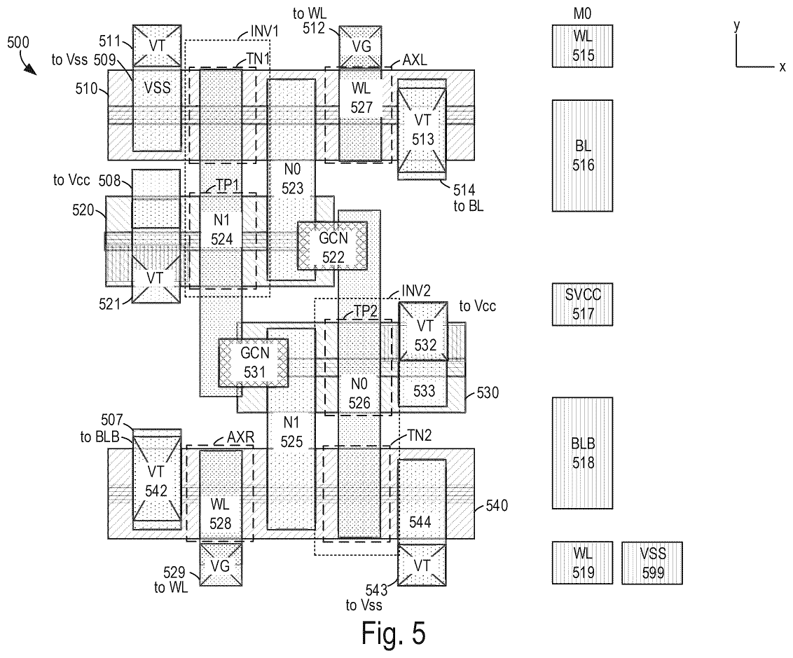

FIG. 5 depicts an example plan view of a comparative SRAM cell 500 without CFET technology, consistent with FIG. 4, in accordance with various embodiments. This cell has a relatively large height (y dimension). The x dimension represents width. The view is in the x-y plane looking from a top or front side of the cell (a side of the cell facing away from the substrate on which the cell is formed). The bottom or back side of the cell is a side of the cell facing the substrate. Various regions are depicted with patterns which are used in the different figures. A region with an “X” generally denotes a via extending in the z direction, either toward or away from the substrate. The regions are depicted with some transparency so that some underlying regions remain visible. The transistors are provided on a common level of the device since CFET is not used. Additionally, a bottom metal layer beneath the transistors is used to connect voltages/signals to the transistors. Vias are used to connect the transistors to the bottom metal layer. The transistors include TN1 and TP1 in INV1, and TN2 and TP2 in INV2, and AXL and AXR. TN1 and AXL are in an n-type transistor region 510, TP1 and TP2 are in p-type transistor regions 520 and 530, respectively, and AXR and TN2 are in an n-type transistor region 540.

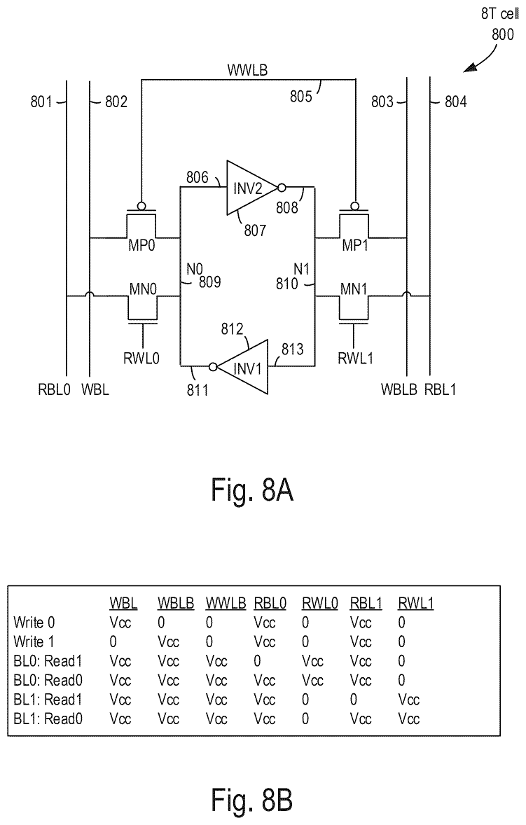

The various nodes, word lines and other conductive paths on the pMOS and nMOS layers as depicted herein in various figures may include a conductive material such as doped polysilicon. In some cases, the doped polysilicon contacts a source/drain region of a transistor as a trench contact (TCN). The conductive paths include regions referred to as nodes, word lines and bit lines consistent with FIGS. 4 and 8A, for example. The vias can include metal plated through-vias, for example, or other conductive material. The nodes, word lines and other conductive paths generally extend in an x-y plane while a via generally extends in the z direction.

TN1 has source/drain regions coupled to a conductive path 509 and conductive path N0 523, and a control gate coupled to conductive path N1 524.

TP1 has source/drain regions coupled to a conductive path 508 and a conductive path N0 523, and a control gate coupled to conductive path N1 524. TN2 has source/drain regions coupled to conductive path N1 525 and a conductive path 544, and a control gate coupled to conductive path N0 526. TP2 has source/drain regions coupled to conductive path N1 525 and a conductive path 533, and a control gate coupled to conductive path N0 526. AXL has source/drain regions coupled to conductive path N0 523 and conductive path 514, and a control gate coupled to WL conductive path WL 527. AXR has source/drain regions coupled to a conductive path 507 and conductive path N1 525, and a control gate coupled to WL conductive path WL 528.

The top metal layer M0 can include a WL portion 515 which carries a voltage to WL 527 using the VG via 512, a BL portion 516 which carries a voltage to conductive path 514 at the source/drain of AXL using the VT via 513, a SVCC portion 517 which carries a voltage Vcc to the power supply nodes of the inverters at the conductive path 508 using the VT via 521 and another conductive path 533 using the VT via 532, a BLB portion 518 which carries a voltage to the BLB of the cell at the conductive path 507 using the VT via 542, another WL portion 519 which carries a voltage to the gate of AXR at the conductive path 528 using the VG via 529, and a VSS portion 599 which carries a ground voltage to VT via 543. The WL portions 515 and 519 can be coupled to one another.

In the n-type transistor region 510, VT 511 denotes a via from the conductive path 509 to a ground point in the top metal layer M0. VG 512 denotes a via to couple to the WL conductive path WL to the WL portion 515. WL 527 and WL 528 paths are part of the word line 403. VT 513 denotes a via from the conductive path 514 to the BL portion 516.

In the p-type transistor region 520, VT via 521 extends from the conductive path 508 to the Vcc portion 517. N1 524 denotes a portion of the node N1 which couples the control gates of TN1 and TP1. N0 523 denotes a conductive path from the n-type transistor region 510, between TN1 and AXL, to the p-type transistor region 520, between TP1 and N0 526. Gate contact (GCN) 522 denotes a gate connect path between N0 523 gate and N0 526 diffusion.

In the p-type transistor region 530, GCN 531 denotes a gate connect path between N1 524 gate and N1 525 diffusion. VT via 532 denotes a via from the conductive path 533 to power supply SVCC 517.

In the n-type transistor region 540, VT via 542 extends from the conductive path 507 to the BLB portion 518. Via VG 529 couples WL 528 to WL 527, as mentioned. Via VT 543 extends from the conductive path 544 to a ground point in the metal layer M0.

The conductive paths 509, 523, 514, 508, 525, 533, 507 and 544 can be TCNs for example. The conductive paths 524, 527, 526 and 528 can comprise doped polysilicon, for example.

In the various figures, N0 523 and N0 526 are conductive paths of the node N0, and N1 524 and N1 525 are conductive paths of the node N1 of FIGS. 4 and 8A.

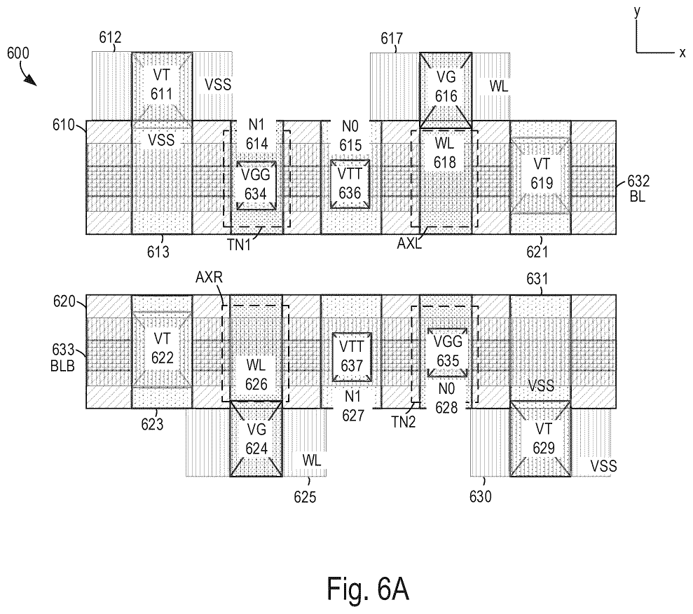

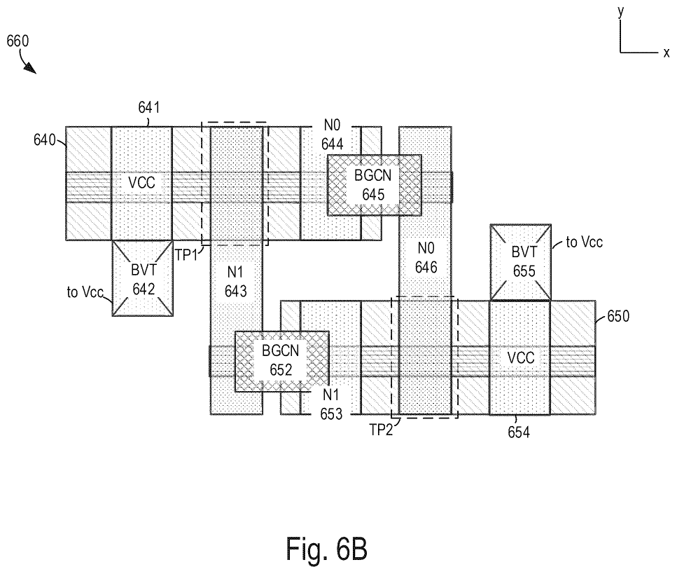

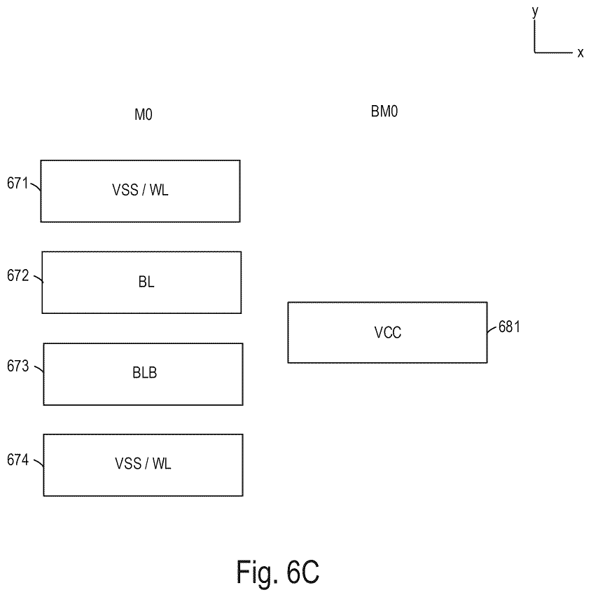

FIG. 6A depicts an example plan view of a front side (FS) 600 of an SRAM cell which uses CFET technology but not intermediate metal layers, consistent with FIG. 4, in accordance with various embodiments. With the help of CFET technology which stacks pMOS and nMOS transistors vertically, the height of the memory cell in the y-direction can be reduced by about one-half. This example implementation includes four nMOS transistors on the front side and two pMOS transistors on the back side.

BL and BLB are routed on the front side M0. The WL and VSS which are shared between bit-cells in the same row are placed along the boundary in the front side M0 on the top and bottom of the layout as depicted. The VCC is routed in the back side M0. The cross-coupled connection nodes N0 and N1 are routed using back side poly and connected to a back side TCN using a BGCN via. Since BL, BLB, VSS and WL are routed in the front side M0, four tracks are used. However, this restricts the maximum width of the tracks, which is problematic to the goal of achieving very low resistance to enable faster read and write operation of the bit-cells. Potentially, new materials for the interconnect such as Cobalt/Copper composite materials can be used to improve the metal resistivity, but this is a process cost adder. The solutions provided herein overcome these challenges.

The front side includes an n-type transistor region 610 with transistors TN1 and AXL, and an n-type transistor region 620 with transistors AXR and TN2. TN1 has source/drain regions coupled to conductive path 613 and conductive path N0 615, and a control gate coupled to a conductive path N1 614. AXL has source/drain regions coupled to N0 615 and a conductive path 621 for a BL, and a control gate coupled to WL conductive path WL 618. AXR has source/drain regions coupled to a conductive path 623 and a conductive path (node region) N1 627, and a control gate coupled to WL conductive path WL 626. TN2 has source/drain regions coupled to the conductive path N1 627 and a conductive path 631 (which is coupled to Vss as a ground node), and a control gate coupled to a conductive path N0 628.

In the n-type transistor region 610, a VT via 611 couples a metal layer portion 612 (e.g., in a front side metal layer such as M0) at Vss to the conductive path 613 at the source/drain of TN1. The conductive path N0 615 is provided on the n-type transistor region 610 between TN1nd AXL. A VG via 616 couples a metal layer portion 617 to the WL conductive path WL 618. A VT via 619 couples the BL 632 to the conductive path 621.

In the n-type transistor region 620, a VT via 622 couples the conductive path 623 to the BLB 633. A VG via 624 couples a metal layer portion 625 to a WL conductive path 626. The WL 618 and WL 626 conductive paths are coupled to one another via the metal layer. The conductive path N1 627 is provided on the n-type transistor region 620 between AXR and TN2. The conductive path N0 628 is coupled to the control gate of TN2. A VT via 629 couples a metal layer portion 630 at Vss to the conductive path 631 at a source/drain of TN2.

The metal layer portions 612, 617, 625 and 630 are example portions which extend further (not shown) in the x-y plane to appropriate voltage sources or ground nodes.

The conductive paths 613, 615, 621, 623, 627 and 631 can be TCNs for example. The conductive paths 614, 618, 626 and 628 can comprise doped polysilicon, for example.

FIG. 6B depicts an example plan view of a back side (BS) 660 of the SRAM cell of FIG. 6A in accordance with various embodiments. The back side includes a p-type transistor region 640 with the transistor TP1 and a p-type transistor region 650 with the transistor TP2. In the p-type transistor region 640, a BVT via 642 couples a conductive path 641, at a source/drain of TP1, to a metal layer carrying a power supply voltage, Vcc. TP1 has source/drain regions coupled to the conductive path 641 and conductive path N0 644, and a control gate coupled to a conductive path N1 643. TP2 has source/drain regions coupled to a conductive path N1 653 and a conductive path 654 (coupled to Vcc as a power supply node), and a control gate coupled to conductive path N0 646. The BGCN 645 couples the conductive path N0 644 to the conductive path N0 646.

In the p-type transistor region 640, a BVT via 642 couples a metal layer portion at Vcc to the conductive path 641 at a source/drain of TP1. The conductive path N1 643 carries a control gate voltage of TP1 and is coupled to the conductive path N1 653 by a BGCN 652. The BGCNs 645 and 652 help reduce the cell height since they provide interconnects within an interior region of the cell.

The conductive path N1 643 is coupled to a conductive path N1 653 by the BGCN via 652. A BVT via 655 couples a metal layer portion at Vcc to the conductive path 654.

VGG via 634 is used to connect between gate N1 614 of TN1 (FIG. 6A) to gate N1 643 of TP1 (FIG. 6B). Similarly, VGG via 635 is used to connect between gate N0 628 of TN2 (FIG. 6A) to gate N0 646 of TP2 (FIG. 6B). VTT via 636 is used to connect between source/drain N0 615 of TN1 (FIG. 6A) to source/drain of N0 644 of TP1 (FIG. 6B). Similarly VTT via 637 is used to connect between source/drain of N1 627 of TN2 (FIG. 6A) to source/drain of N1 653 of TP2 (FIG. 6B).

The conductive paths 641, 644, 653 and 654 can be TCNs for example. The conductive paths 643 and 646 can comprise doped polysilicon, for example.

FIG. 6C depicts an example plan view of a front side metal 0 (M0) layer and a back side base metal 0 (BM0) layer of the SRAM cell of FIG. 6A, in accordance with various embodiments. The M0 layer includes portions 671, 672, 673 and 674 representing a Vss path or a WL, a bit line (BL), a complementary bit line (BLB) and a Vss path or WL, respectively. The BM0 layer includes a portion 681 representing a Vcc path. Referring also to FIG. 6A, different instances of the portion 671 represent the metal layer portions 612 and 617, the portion 672 represents the BL 632, the portion 673 represents the BLB 633, and different instances of the portion 674 represent the metal layer portions 625 and 630.

The metal layer portions can have different heights. However, the metal layers 612 and 617 will have same width, and the metal layers 625 and 630 will have the same width, in an example implementation.

The reduction of the cell height puts a constraint on the widths (y-direction) of the metal layers in the front-side (M0). In contrast, the back side BM0 only carries VCC.

The above constraint can be addressed by adding IM layers between the pMOS and nMOS layers in the CFET device such as shown in FIG. 3. This approach can distribute the interconnect signals using the additional IM tracks that are available. In an example implementation, two additional IM layers, IM0 (horizontal or x-direction) and IM1 (vertical or y-direction) can be added between the pMOS and nMOS layers. The N0 and N1 connections can be enabled using the IM0 layer without a GCN, which simplifies the layers that are to be provided. FIGS. 7A-7G provide an example in the context of a 6T SRAM cell, but other examples are possible. In addition, both WL/VSS layers from the top and bottom of the layout can be transferred from M0 to IM0, which reduces the number of tracks used in the M0 from three to two (FIG. 7B). As a result, with an identical M0 pitch, the dimensions of BL and BLB can be increased by about 30%, which reduces the resistance by about 24%.

To achieve the same BL and BLB as with the original SRAM layout, the bit cell height may be increased, resulting in about a 17% area increase. As a result of moving one of WL/VSS from M0 to IM0, the WL can be routed in IM1 instead of M1 as shown in FIG. 7D. Three tracks are used in IM0 (FIG. 7E). However, the resistance of the signals at N0 and N1 is not as critical as the resistance of the BL and BLB signals. Similarly, other multi-port on-chip memories such as one-read, one-write (1R1 W) and two-read, one write (2R1 W) can also exploit the intermediate layers to improve the area, the BL/BLB resistance, or both.

FIG. 7A depicts an example plan view of a front side 700 of a 6T SRAM cell which uses CFET technology and IM layers, consistent with FIG. 4, in accordance with various embodiments. The front-side has four nMOS transistors/devices. Two WL/Vss tracks are moved from the front side to the IM0 tracks while Vcc track on the bottom side are retained. Specifically, this example modifies the example of FIG. 6A by moving the metal layer portions 612, 617, 625 and 630 from the top side to one or more intermediate layers. Instead, in FIG. 7A, the conductive paths 711, 714, 722 and 725 are coupled to the intermediate layers below the front side using vias 711a, 714a, 722a and 725a, respectively. See also FIG. 7B.

The front side 700 includes a first n-type transistor region 710 with the transistors TN1 and AXL, and a second n-type transistor region 720 with transistors AXR and TN2. TN1 has source/drain regions coupled to the conductive path 711 and conductive path N0 713, and a control gate coupled to a conductive path N1 712. AXL has source/drain regions coupled to the conductive path N0 713 and a conductive path 715, and a control gate coupled to WL conductive path WL 714. The conductive path 715 is coupled to BL 726 by a VT via 716. AXR has source/drain regions coupled to a conductive path 721 and conductive path N1 723, and a control gate coupled to WL conductive path WL 722. The conductive path 721 is coupled to BLB 727 by a VT via 729. TN2 has source/drain regions coupled to conductive path N1 723 and conductive path 725 (which is coupled to Vss), and a control gate coupled to conductive path N0 724.

The conductive paths 711, 713, 715, 721, 723 and 725 can be TCNs for example. The conductive paths 712, 714, 722 and 724 can comprise doped polysilicon, for example.

In an example implementation, a system comprises a processor 1252; and a memory 1254 coupled to the processor, wherein the memory comprises a static random access memory (SRAM) cell 400, and the SRAM cell comprises: a p-type transistor layer 215, 761, 770 comprising p-type transistors TP1, TP2; an n-type transistor layer 220, 710, 720 comprising n-type transistors TN1, TN2, wherein the n-type transistor layer is above the p-type transistor layer; and one or more intermediate metal layers 240 IM0, 250 IM1 between the p-type transistor layer and the n-type transistor layer, wherein the one or more intermediate metal layers are coupled to the p-type transistor layer and to the n-type transistor layer.

FIG. 7B depicts an example plan view of an intermediate layer 750 of the SRAM cell of FIG. 7A, including intermediate metal layer IM0, in accordance with various embodiments. WL/VSS are moved to IM layer tracks. The BGCNs are replaced by IM layer N0 and N1 tracks. The use of the IM layer tracks is friendlier to process scaling compared to adding a new via layer BGCN in the sequential flow.

The intermediate layer includes IM0 portions 730, 732, 734, 737, 740 and 741 as conductive paths. The IM0 portion 730 represents a Vss track and is coupled to the conductive path 711 in FIG. 7A by the IVTF via 711a. The IM0 portion 732 represents a WL track and is coupled to the conductive path 714 in FIG. 7A by the IVGF via 714a. The IM0 portion 734 represents an N0 track and is coupled to the conductive paths 766 and 772 in FIG. 7C by the IVTB via 735 and the IVGB via 736, respectively. The IM0 portion 737 represents an N1 track and is coupled to the conductive paths 764 and 771 in FIG. 7C by the IVGB via 738 and the IVTB via 739, respectively. The IM0 portion 740 represents a WL track and is coupled to the conductive path 722 in FIG. 7A by the IVGF via 722a. The IM0 portion 741 represents a Vss track and is coupled to the conductive path 725 in FIG. 7A by the IVTF via 725a. As shown in FIG. 7A the node N0A is connected to N0 in IM0 using IVTF via 728. Similarly, node N1 723 is connected to N1 in IM0 using IVTF via 729.

The VGG via 777 is used to couple the conductive path N0 772 to N0 724 in FIG. 7A, and to connect the gates between TP2 (N0 772) and TN2 (N0 724). Similarly, VGG via 778 is used to couple the conductive path 764 to 712 in FIG. 7A, and to connect the gates between TP1 (N1 764) and TN1 N1 (N1 712).

The IM0 portions may extend further (not shown) in the x-y plane and in the z direction, including through IM1, to appropriate voltage sources or ground nodes.

The IM0 portions are this coupled to both the pMOS and nMOS layers.

FIG. 7C depicts an example plan view of a back side 760 of the SRAM cell of FIG. 7A in accordance with various embodiments. The back side includes two pMOS transistors. The back side poly N0 and N1 are extended to the IM0 layer which then connects to the back side diffusion (via a TCN). VGG via 778 is used to connect the gates of TP1 and TN1, and VGG via 77 is used to connect the gates of TP2 and TN2.

The back side includes a first p-type transistor region 761 with the transistor TP1 and a second p-type transistor region 770 with the transistor TP2. TP1 has source/drain regions coupled to conductive path 762 and conductive path N0c 766, and a control gate coupled to a conductive path N1 764. TP2 has source/drain regions coupled to conductive path N1 771 and a conductive path 775, and a control gate coupled to conductive path N0 772. The vias 735 and 736 of FIG. 7B are depicted which couple the conductive path N0 766 to the conductive path N0 772 through the IM layer portion 734. The vias 738 and 739 of FIG. 7B are also depicted which couple N1 764 to the conductive path N1 771 through the IM layer portion 737.

The BVT via 763 couples the conductive path 762 to Vcc such as through a bottom metal layer. The BVT via 776 couples the conductive path 775 to Vcc such as through a bottom metal layer.

The conductive paths 762, 766, 771 and 775 can be TCNs for example. The conductive paths 764 and 772 can comprise doped polysilicon, for example.

The conductive paths N0 713, N0 724, N0 766 and −N0 772 can be considered to be conductive paths which are coupled to, or part of, the node N0 401 (FIG. 4), and the conductive paths N1 712, N1 723, N1 764 and −N1 771 can be considered to be conductive paths which are coupled to, or part of, the node N1 402.

FIG. 7D depicts an example plan view of a front side M0 layer of the SRAM cell of FIG. 7A, in accordance with various embodiments. The M0 layer includes two tracks, e.g., portions 780 and 781 representing BL and BLB, respectively. The portions 780 and 781 represent BL 726 and BLB 727, respectively, of FIG. 7A, for example.

FIG. 7E depicts an example plan view of a first intermediate metal layer (IM0) of the SRAM cell of FIG. 7A, in accordance with various embodiments. The IM0 layer has three tracks. Specifically, the IM0 layer includes a portion 785 representing a Vss path or WL, a portion 786 which represents the node N0 734 in FIG. 7B, a portion 787 which represents the node N1 737 in FIG. 7B, and a portion 788 which represents a Vss path or WL. One instance of the portion 785 can represent the Vss metal layer portion 730 and another instance of the portion 785 can represent the WL metal layer portion 732, for example. One instance of the portion 788 can represent the WL metal layer portion 740 and another instance of the portion 788 can represent the Vss metal layer portion 741, for example.

FIG. 7F depicts an example plan view of a second intermediate metal layer (IM1) of the SRAM cell of FIG. 7A, in accordance with various embodiments. IM1 includes word line metal layer portions 790 and 791 representing the WL. These metal layers are coupled to corresponding IM0 metal layers 785 and 788.

FIG. 7G depicts an example plan view of a back side BM0 layer of the SRAM cell of FIG. 7A, in accordance with various embodiments. The back side layer has one track. Specifically, BM0 includes a portion 795 representing a Vcc path or track. The track can be coupled to the BVT vias 763 and 776, for example.

Accordingly, it can be seen that the examples herein include a complementary field-effect transistor (CFET) device, comprising: one or more bottom metal layers; a p-type transistor layer above the one or more bottom metal layers; one or more intermediate metal layers above the p-type transistor layer; an n-type transistor layer above the one or more intermediate metal layers; and one or more top metal layers above the n-type transistor layer, wherein: the one or more bottom metal layers are coupled to the p-type transistor layer; the one or more intermediate metal layers are coupled to the p-type transistor layer and to the n-type transistor layer; and the one or more top metal layers are coupled to the n-type transistor layer.

FIG. 8A depicts an example circuit diagram of an eight-transistor (8T) SRAM memory cell 800, in accordance with various embodiments. The cell includes first and second inverters INV1 812 and INV2 807, respectively, and first and second cross-coupled nodes N0 809 and N1 810, respectively. First and second read bit lines, RBL0 801 and RBL1 804, respectively, and first and second write bit lines, WBL 802 and WBLB 803, respectively, are also depicted. N0 is coupled to WBL by a p-type transistor MP0 and to RBL0 by an n-type transistor MN0. N1 is coupled to WBLB by a p-type transistor MP1 and to RBL1 by an n-type transistor MN1. INV1 has an input 813 and an output 811. INV2 has an input 806 and an output 808. MP0 and MP1 receive a control gate voltage from a write word line WWLB 805, MN0 receives a control gate voltage RWL0, and MN1 receives a control gate voltage RWL1.

A circuit implementation of the inverters can be provided as depicted in FIG. 4.

The solutions provided herein can enable a more symmetric design with four nMOS and four pMOS transistors. Write is enabled through two pMOS transistors, MP0 and MP1. On the other hand, a read port uses single ended reading with RWL0 enabling reading through RBL0 at MN0, and RWL1 enabling reading through RBL1 at MN1. The cell may be implemented as a two-read, one write (2R1 W) cell. The table of FIG. 8B shows the comparison of read, write and retention operations in an example implementation.

FIG. 8B depicts an example table of word line and bit line voltages for write, read and retention operations in the SRAM cell 800 of FIG. 8A, in accordance with various embodiments. To write a 0 bit, WBL, WBLB, WWLB, RBL0, RWL0, RBL1 and RWL1 are set to Vcc, 0 V, 0 V, Vcc, 0 V, Vcc and 0 V, respectively. To write a 1 bit, WBL, WBLB, WWLB, RBL0, RWL0, RBL1 and RWL1 are set to 0 V, Vcc, 0 V, Vcc, 0 V, Vcc and 0 V, respectively. For a RBL0 read1 operation using BL0, WBL, WBLB, WWLB, RWL0, RBL1 and RWL1 are set to Vcc, Vcc, Vcc, Vcc, Vcc and 0 V, respectively. RBL0 will discharge from Vcc to 0V due the read1 operation. For a RBL0 read0 operation using BL0, WBL, WBLB, WWLB, RWL0, RBL1 and RWL1 are set to Vcc, Vcc, Vcc, Vcc, Vcc and 0 V, respectively. RBL0 will stay at the pre-charged voltage Vcc due to the read0 operation. For a RBL1 read1 operation using BL1, WBL, WBLB, WWLB, RBL0, RWL0, and RWL1 are set to Vcc, Vcc, Vcc, Vcc, 0 V and Vcc, respectively. RBL1 will discharge from Vcc to 0V due the read1 operation. For a RBL1 read0 operation using BL1, WBL, WBLB, WWLB, RBL0, RWL0 and RWL1 are set to Vcc, Vcc, Vcc, Vcc, 0 V and Vcc, respectively. RBL1 will stay at the pre-charged voltage Vcc due to the read0 operation.

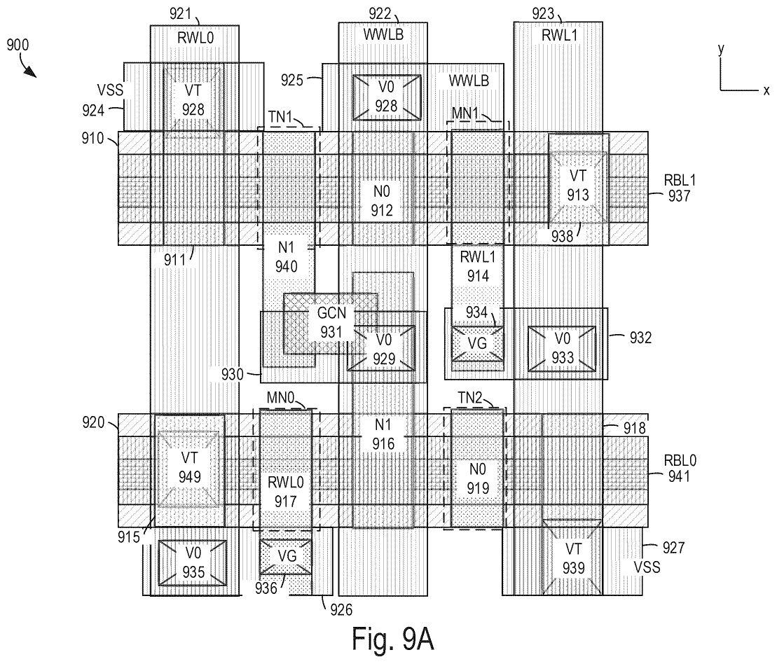

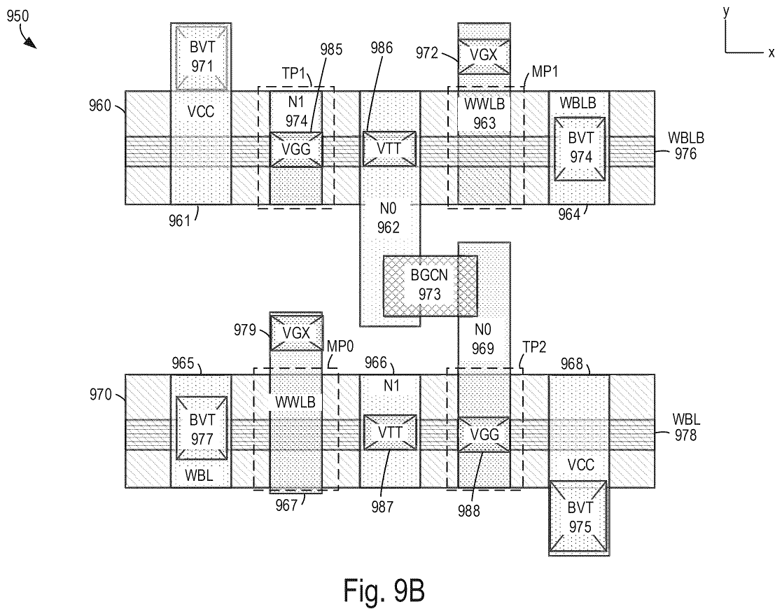

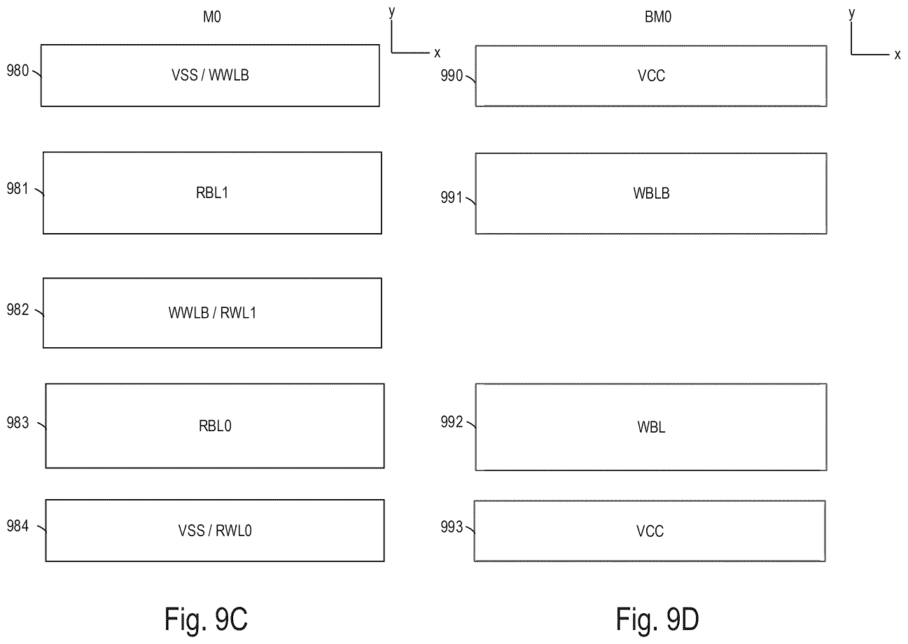

FIG. 9A depicts an example plan view of a front side 900 of an 8T SRAM cell which uses CFET technology but without intermediate metal layers, consistent with FIG. 8A, in accordance with various embodiments. In the example implementation of FIGS. 9A-9D, all four nMOS transistors are on the front side and all four pMOS transistors are on the back side. The gates of the write pass gates MP0 and MP1 are connected to WWLB through a VGX via 974 and 972, respectively, from back side poly (POLYB) to the front side M0 and then connected to M1 (in the center of the layout) through a V0 via 929. Definitions for the different via layers used in the CFET layout are shown in FIG. 11.

The write bit lines WBL and WBLB are routed through the back side metal layer (BM0) which is connected from the back side TCN region (BTCN) through the BVT via. Read transistors MN0 and MN1 are activated by RWL0 and RWL1, respectively with RWL0 M1 routing done on the left side of the cell and RWL1 M1 routing done on the right side of the cell. RWL0 and RWL1 are connected to MN0 and MN1, respectively, through a VG via 936 or 934, respectively, followed by M1 926 or 932, respectively, and then by a V0 via 935 or 933, respectively, to M0. The corresponding RBL0 and RBL1 are routed in M0 in layers 937 and 941, respectively.

The cross-coupled N1 connection is enabled through a front side GCN 931 between a conductive path 940 (front side poly) and a front side conductive path N1 916. Another cross-coupled connection N0 is enabled through a back side GCN, or BGCN region 973, between a conductive region back side poly 962 (back side poly) and BTCN 969. The benefit of the proposed 2 poly-pitch (2PP) layout is the highest metal layer used in the front side is M1 and the lowest metal layer used in the back side is BM0, resulting in lower capacitance and hence higher performance for both read and write operations. One poly pitch represents spacing between two near polys. 2PP indicates that the width of the SRAM is equal to 2 poly-pitches. Due to a short cell height, the widths of RBL0/RBL1 and WBL/WBLB can be restricted. See FIG. 9C.

The front side includes an n-type transistor region 910 with transistors TN1 and MN1, and an n-type transistor region 920 with transistors MN0 and TN2. TN1 has source/drain regions coupled to a conductive path 911 and conductive path N0 912, and a control gate coupled to conductive path N1 940. MN1 has source/drain regions coupled to the conductive path N0 912 and a conductive path 913, and a control gate coupled to a RWL1 conductive path 914 (e.g., polysilicon). MN0 has source/drain regions coupled to a conductive path 915 and the conductive path N1 916, and a control gate coupled to a RWL0 conductive path 917 (polysilicon). TN2 has source/drain regions coupled to the conductive path N1 916 and conductive path 918, and a control gate coupled to conductive path N0 919.

Metal layer portions 921, 922 and 923 can be provided in one metal layer while metal layer portions 924, 925, 926, 927, 930 and 932 are in another metal layer.

The metal layer portion 924 at Vss is coupled by a VT via 928 to the conductive path 911.

The metal layer portion 925 representing WWLB is coupled by a V0 via 928 to the WWLB metal layer portion 922, which in turn can be coupled to the metal layer 937 which is then connected to node layer 967 through the VGX via 979. This is how WWLB is provided to the control gate of MP0. Similarly, control gate of MP1 is connected to metal layer 925 using the VGX via 972 which is connected to VWWLB.

The conductive path N1 is in turn coupled to the conductive path N1 940 by a GCN 931.

The metal layer portion 923 representing RWL1 is coupled to the metal layer portion 932 by a V0 via 933, and from the metal layer portion 932 to the RWL1 conductive path 914 by a VG via 934. This is how VRWL1 is provided to the control gate of MN1.

The metal layer portion 921 representing RWL0 is coupled to the metal layer portion 926 by the V0 via 935, and from the metal layer portion 926 to the RWL0 conductive path 917 by a VG via 936. This is how VRWL0 is provided to the control gate of MN0.

RBL1 937 is coupled to the conductive path 913 by a VT via 938.

Metal layer portion 927 at Vss is provided to the conductive path 918 by a VT via 939.

RBL0 941 at a voltage VRBL0 is provided to the conductive path 915 by a VT via 949.

The conductive paths 911, 915, 913 916 and 918 can be TCNs for example. The conductive paths 940, 914, 917 and 919 can comprise doped polysilicon, for example.

FIG. 9B depicts an example plan view of a back side 950 of the SRAM cell of FIG. 9A in accordance with various embodiments. The back side includes a p-type transistor region 960 with transistors TP1 and MP1, and a p-type transistor region 970 with transistors MP0 and TP2. TP1 has source/drain regions coupled to a conductive path 961 and conductive path N0 962, and a control gate coupled to conductive path N1 974. The conductive path N1 974 is connected to conductive path N1 940 using the VGG via 985. The conductive path N0 962 is connected to conductive path N0 912 using the VTT via 986.

MP1 has source/drain regions coupled to the conductive path N0 962 and a conductive path 964, and a control gate coupled to a conductive path 963 representing WWLB. MP0 has source/drain regions coupled to a conductive path 965 representing WBL and a conductive path 966, and a control gate coupled to a conductive path 967 representing WWLB. TP2 has source/drain regions coupled to the conductive path N1 966 and conductive path 968, and a control gate coupled to conductive path N0 969. The conductive path N0 969 is connected to conductive path N0 919 using the VGG via 988. The conductive path N1 966 is connected to conductive path N1 916 using the VTT via 987.

A BVT via 971 is used to couple Vcc to the conductive path 961. A VGX via 972 is used to couple WWLB to the conductive path 925. A BVT via 974 is used to couple the conductive path 964 to WBLB 976. A BVT via 977 is used to couple the conductive path 965 to WBL 978. A VGX via 979 is used to couple WWLB to the conductive path 930.

A back gate contact (BGCN) 973 is used to couple N0 962 to N0 969.

A BVT via 975 is used to couple Vcc to the conductive path 968.

The conductive paths 961, 962, 964, 965, 966 and 968 can be TCNs for example. The conductive paths 974, 963, 967 and 969 can comprise doped polysilicon, for example.

FIG. 9C depicts an example plan view of a front side M0 layer of the SRAM cell of FIG. 9A, in accordance with various embodiments. RBL0 and RBL1 are routed in M0 while WBL and WBLB are routed in BM0. In particular, the M0 layer includes a portion 980 representing a Vss path or WWLB, a portion 981 representing RBL1, a portion 982 representing WWLB or RWL1, a portion 983 representing RBL0 and a portion 984 representing a Vss path or RWL0. Separate instances of the portion 980 can represent the metal layer portions 924 and 925. The portion 981 represents RBL1 937. Separate instances of the portion 982 represent the metal layer portions 930 and 932. The portion 983 represents RBL0 941. Separate instances of the portion 984 represent the metal layer portions 917 and 927.

FIG. 9D depicts an example plan view of a back side BM0 layer of the SRAM cell of FIG. 9A, in accordance with various embodiments. The BM0 layer includes a portion 990 representing a Vcc path, a portion 991 representing WBLB, a portion 992 representing WBL, and a portion 993 representing a Vcc path. The portions 990, 991, 992 and 993 can represent metal layers coupled to the BVT vias 971, 974, 977 and 975, respectively. The portion 991 can represent WBLB 976. The portion 992 can represent WBL 978.

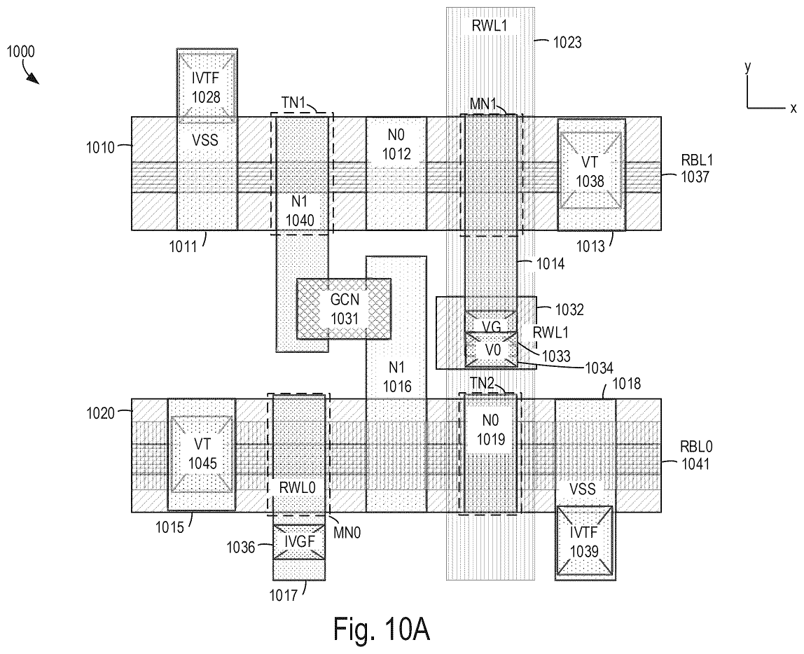

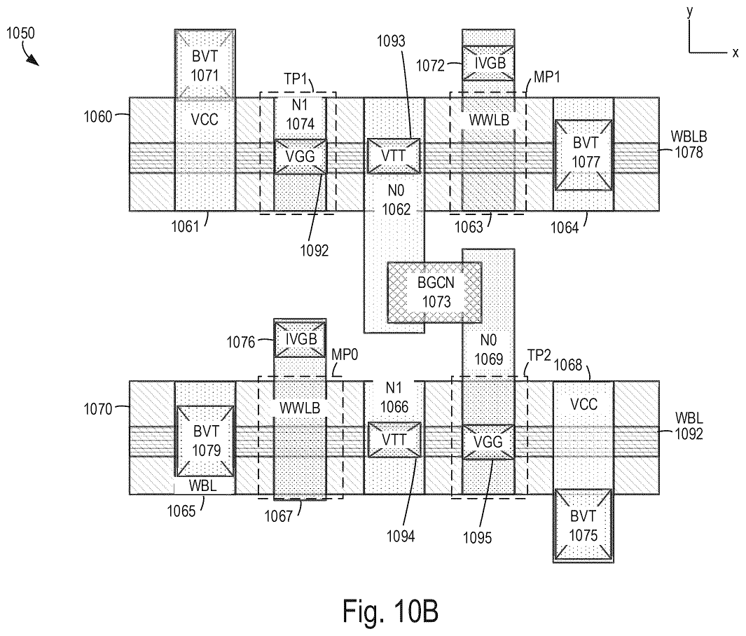

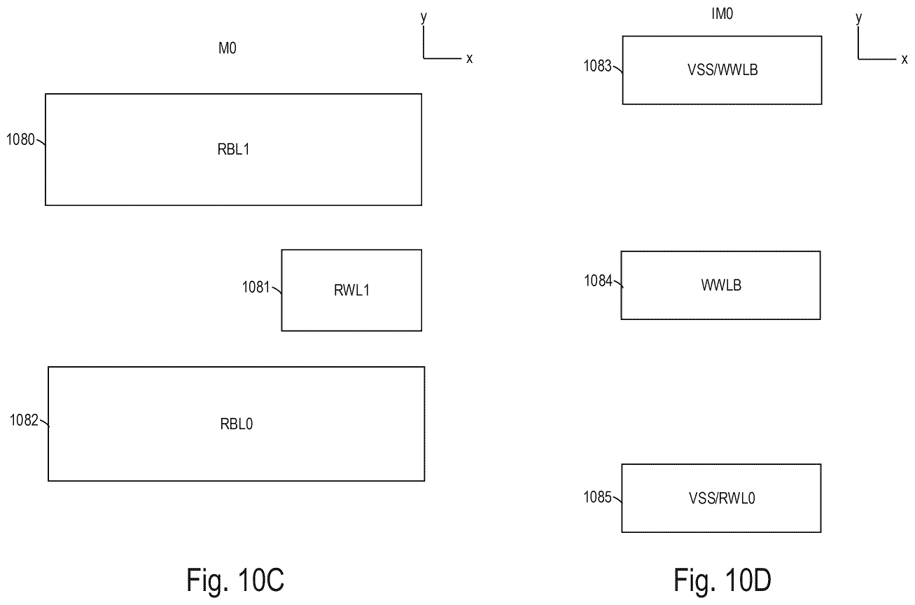

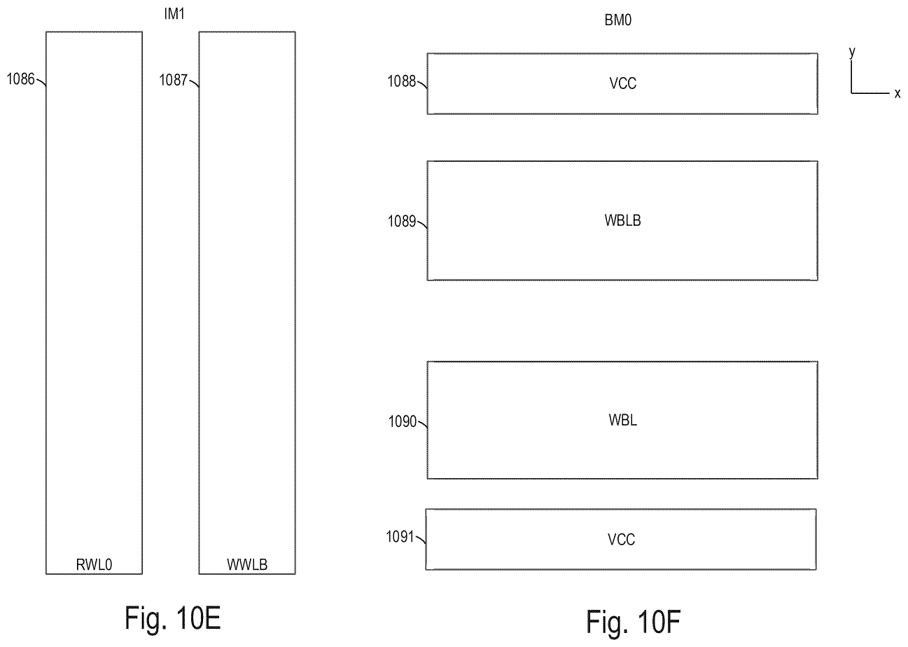

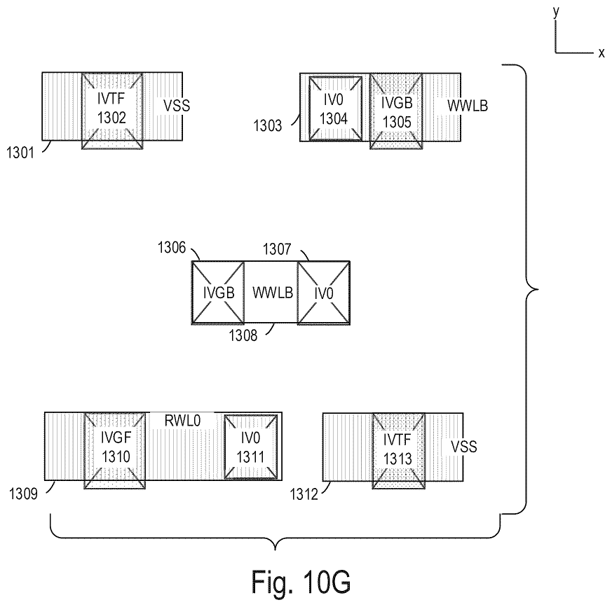

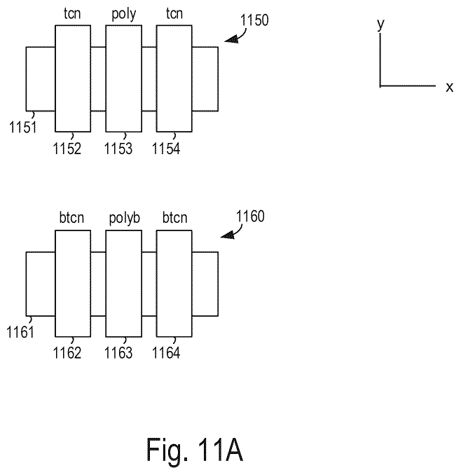

FIG. 10A depicts an example plan view of a front side 1000 of an 8T SRAM cell which uses CFET technology and intermediate metal layers, consistent with FIG. 8A, in accordance with various embodiments. With the help of the IM layers, the resistance can be reduced for RBL0, RBL1, WBL and WBLB. FIGS. 10A-10F provide an example implementation of an 8T 2R-1 W SRAM cell with VSS/RWL0 and VSS/WWLB moved from M0 to IM0. This provides extra space in the front side which can be used to increase the widths (y-direction) of RBL0 and RBL1, thereby reducing their resistance. Similarly, the widths of WBL and WBLB can also be increased. Moreover, RWL0 and WWLB are moved from M1 to IM1, thus enabling wider widths for RWL0, RWL1 and WWLB, all of which were on M1 in the comparative design of FIGS. 9A-9D. RWL1 remains in M1.

The front side includes a first n-type transistor region 1010 with transistors TN1 and MN1, and a second n-type transistor region 1020 with transistors MN0 and TN2. TN1 has source/drain regions coupled to a conductive path 1011 and conductive path N0 1012, and a control gate coupled to conductive path N1 1040. MN1 has source/drain regions coupled to the conductive path N0 1012 and a conductive path 1013, and a control gate coupled to a RWL1 conductive path 1014. MN0 has source/drain regions coupled to a conductive path 1015 and conductive path N1 1016, and a control gate coupled to RWL0 conductive path 1017. TN2 has source/drain regions coupled to the conductive path N1 1016 and conductive path 1018, and a control gate coupled to conductive path N0 1019.

The conductive path N1 1016 is coupled to the conductive path N1 1040 by a GCN gate contact 1031.

The M1 metal layer portion 1023 representing RWL1 is coupled to the M0 metal layer portion 1032 by V0 via 1034. Metal layer portion 1032 is then connected to conductive region 1014 through a VG via 1033.

RBL1 1037 is coupled to the conductive path 1013 by a VT via 1038.

RBL0 1041 is coupled to the conductive path 1015 by a VT via 1045.

Vss is coupled by a IVTF via 1028 to the conductive path 1011.

Vss is coupled by a IVTF via 1039 to the conductive path 1018.

RWL0 is coupled to the conductive path 1017 by a IVGF via 1036.

The conductive path N1 1040 is the gate of INV1 in FIG. 8A. The conductive path N1 1016 is the input 806 of INV2 in FIG. 8A. The conductive path N0 1012 is the output 811 of INV1 in FIG. 8A. The conductive path N0 1019 is the gate of INV2 in FIG. 8A.

The conductive paths 1011, 1012, 1013, 1015, 1016 and 1018 can be TCNs for example. The conductive paths 1040, 1014, 1017 and 1019 can comprise doped polysilicon, for example.

FIG. 10B depicts an example plan view of a back side 1050 of the SRAM cell of FIG. 10A in accordance with various embodiments. The back side includes a first p-type transistor region 1060 with transistors TP1 and MP1, and a second p-type transistor region 1070 with transistors MP0 and TP2. TP1 has source/drain regions coupled to a conductive path 1061 and conductive path N0c 1062, and a control gate coupled to conductive path N1 1074. MP1 has source/drain regions coupled to the conductive path N0 1062 and a conductive path 1064, and a control gate coupled to a conductive path 1063 representing WWLB. MP0 has source/drain regions coupled to a conductive path 1065 and a conductive path N1 1066, and a control gate coupled to a conductive path 1067 representing WWLB. TP2 has source/drain regions coupled to the conductive path N1 1066 and conductive path 1068, and a control gate coupled to conductive path N0 1069.

The conductive path N1 1074 is connected to conductive path N1 1040 using the VGG via 1092. The conductive path N0 1062 is connected to conductive path N0 1012 using the VTT via 1093.

The conductive path N0 1069 is connected to conductive path N0 1019 using the VGG via 1095. The conductive path N1 1066 is connected to conductive path N1 1016 using the VTT via 1094.

A BVT via 1071 is used to couple Vcc to the conductive path 1061. A IVGB via 1072 is used to couple WWLB to the conductive path 1063. A BVT via 1077 is used to couple the conductive path 1064 to WBLB 1078. A BVT via 1079 is used to couple the conductive path 1065 to WBL 1092.

A back gate contact (BGCN) 1073 is used to couple N0 1062 to N0 1069.

An IVGB via 1076 is used to couple WWLB to the conductive path 1067. A BVT via 1075 is used to couple Vcc to the conductive path 1068.

The conductive paths 1061, 1062, 1064, 1065, 1066 and 1068 can be BTCNs for example. The conductive paths 1074, 1063, 1067 and 1069 can comprise doped polysilicon, for example.

FIG. 10C depicts an example plan view of a front side M0 layer of the SRAM cell of FIG. 10A, in accordance with various embodiments. The front side includes metal layer portions 1080, 1081 and 1082 representing RBL1, RWL1 and RBL0, respectively. For example, the portions 1080, 1081 and 1082 can represent RBL1 1037, RWL1 1032 and RBL0 1041, respectively.

FIG. 10D depicts an example plan view of a first intermediate metal layer (IM0) of the SRAM cell of FIG. 10A, in accordance with various embodiments. IM0 includes metal layer portions 1083, 1084 and 1085 representing Vss or WWLB, WWLB and Vss or RWL0, respectively. For example, separate Vss or WWLB instances of the portion 1083 can be coupled to the IVTF via 1028 and IVGB via 1072, respectively. The portion 1084 can be coupled to the IVG via 1076. Separate Vss or RWL0 instances of the portion 1085 can be coupled to the IVTF via 1039 and IVGF via 1036, respectively.

FIG. 10E depicts an example plan view of a second intermediate metal layer (IM1) of the SRAM cell of FIG. 10A, in accordance with various embodiments. IM1 includes metal layer portions 1086 and 1087 representing RWL0 and WWLB, respectively. These portions can be coupled to the like-named portions in FIG. 10D. The RWL0 portion 1085 in IM0 is connected to RWL1 1086 in IM1 through an IVO via. Similarly, the WWLB portion 1083 in IM0 is connected to WWLB 1087 in IM1 through an IVO via. The IM0 metal layer 1084 of WWLB is also connected to WWLB 1087 in IM1 through an IVO via.

As mentioned, RWL0 and WWLB are moved from M0 to IM1, relative to the design of FIGS. 9A-9D.

FIG. 10F depicts an example plan view of a back side BM0 layer of the SRAM cell of FIG. 10A, in accordance with various embodiments. BM0 includes metal layer portions 1088, 1089, 1090 and 1091 representing Vcc, WBLB, WBL and Vcc. respectively. The portion 1088 can be coupled to the BVT via 1071 to Vcc, the portion 1089 can represent WBLB 1078, the portion 1090 can represent WBL 1092 and the portion 1091 can couple to the BVT via 1075 to Vcc.

FIG. 10G depicts an example of the intermediate IM0 layer of the SRAM cell of FIG. 10A, in accordance with various embodiments. The IM0 layer portion 1301 represents the VSS portion of the IM0 portion 1083 in FIG. 10D which is connected to the IM0 layer portion 1301 through the IVTF via 1302. The IM0 layer portion 1312 represents the VSS portion of the IM0 portion 1085 in FIG. 10D which is connected to the conductive path 1018 through the IVTF via 1313. The IM0 layer portion 1309 which represents RWL0 is connected to the conductive path 1017 in FIG. 10A through the IVGF via 1310. The IM0 layer portion 1309 is then connected to the IM1 portion 1086 using the IVO via 1311. The IM0 layer portion 1308 is connected to the layer/conductive path 1067 through and the IVGB via 1306. The IM0 layer 1308 is the connected IM1 layer portion 1087 through an IVO via 1307. The WWLB layer 1303 which is an instance of the IM0 portion 1083, is connected to the conductive path 1063 through an IVGB via 1305. The WWLB layer 1303 is then connected to the IM1 layer portion 1087 using an IVO via 1304.

FIGS. 11A and 11B provide examples of layers used in the CFET process.

FIG. 11A depicts an example view of an n-type metal-oxide-semiconductor field-effect transistor (nMOSFET or nMOS) 1150 and p-type MOSFET (pMOS) 1160, in accordance with various embodiments. The nMOS 1150 includes an active area 1151 and conductive paths ton 1152, poly 1153 and ten 1154, which extend over the active area in the x-y plane. The pMOS 1160 includes an active area 1161 and conductive paths bten 1162, polyb 1163 and bten 1164, which extend over the active area in the x-y plane. See also FIG. 11B.

FIG. 11B depicts an example perspective view of different layers and vias in an SRAM cell which uses CFET technology and intermediate metal layers, consistent with FIGS. 7A-7D and 10A-10F, in accordance with various embodiments. Starting at the bottom, in ascending order, there are bottom metal layers BM1 1101 and BM0 1103, a pMOS layer 1165, a first IM layer IM1, a second IM layer IM0, an nMOS layer 1170, and first, second and third top metal layers M0, M1 and M2, respectively.

A via bv0 1102 is used to couple BM1 1101 to BM0 1103. Vias bvt 1104 and bvg 1105 are used to couple BM0 to bten 1106 and polyb 1107, respectively, which are conductive paths which extend in the x-y plane.

Vias ivtb 1110 and ivgb 1111 are used to couple btcn 1106 and polyb 1107, respectively, to IM0 1114. A via iv0 1112 is used to couple IM1 1113 to IM0 1114. Vias ivtf 1115 and ivgf 1116 are used to couple IM0 1114 to ten 1117 and poly 1118, respectively, which are conductive paths which extend in the x-y plane. Vias v1 1120 and vg 1121 are used to couple tcn 1117 and poly 1118, respectively, to M0 1122. A via v0 1123 is used to couple M0 1122 to M1 1124. A via v1 1125 is used to couple M1 1124 to M2 1126.

The poly layer 1126 can be directly connected to bpoly layer 1108 using vgg via 1127. The ten layer 1119 can be directly connected to bten layer 1109 using vtt via 1129.

Use of a shorter via to connect to the nMOS or pMOS layer a metal layer is preferable to reduce capacitance and complexity. The closest metal layer may be below or above in different cases.

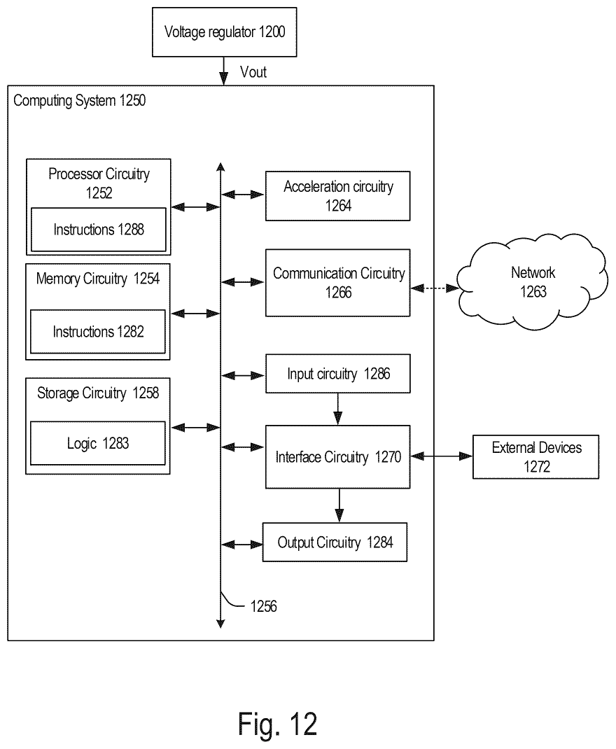

FIG. 12 illustrates an example of components that may be present in a computing system 1250 for implementing the techniques (e.g., operations, processes, methods, and methodologies) described herein. The CFET memory cell described herein can be used in any of the components of the computing system 1250. One example implementation involves the memory circuitry 1254.

The voltage regulator 1200 may provide a voltage Vout to one or more of the components of the computing system 1250.

The memory circuitry 1254 may store instructions and the processor circuitry 1252 may execute the instructions to perform the functions described herein.

The computing system 1250 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1250, or as components otherwise incorporated within a chassis of a larger system. For one embodiment, at least one processor 1252 may be packaged together with computational logic 1282 and configured to practice aspects of various example embodiments described herein to form a System in Package (SiP) or a System on Chip (SoC).

The system 1250 includes processor circuitry in the form of one or more processors 1252. The processor circuitry 1252 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1252 may include one or more hardware accelerators (e.g., same or similar to acceleration circuitry 1264), which may be microprocessors, programmable processing devices (e.g., FPGA, ASIC, etc.), or the like. The one or more accelerators may include, for example, computer vision and/or deep learning accelerators. In some implementations, the processor circuitry 1252 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1252 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1252 may be coupled with or may include memory/storage and may be configured to execute instructions stored in the memory/storage to enable various applications or operating systems to run on the platform 1250. The processors (or cores) 1252 is configured to operate application software to provide a specific service to a user of the platform 1250. In some embodiments, the processor(s) 1252 may be a special-purpose processor(s)/controller(s) configured (or configurable) to operate according to the various embodiments herein.

As examples, the processor(s) 1252 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1252 may be a part of a system on a chip (SoC), System-in-Package (SiP), a multi-chip package (MCP), and/or the like, in which the processor(s) 1252 and other components are formed into a single integrated circuit, or a single package. Other examples of the processor(s) 1252 are mentioned elsewhere in the present disclosure.

The system 1250 may include or be coupled to acceleration circuitry 1264, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1264 may comprise logic blocks or logic fabric and other interconnected resources that may be programmed (configured) to perform various functions, such as the procedures, methods, functions, etc. of the various embodiments discussed herein. In such implementations, the acceleration circuitry 1264 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1252 and/or acceleration circuitry 1264 may include hardware elements specifically tailored for machine learning and/or artificial intelligence (AI) functionality. In these implementations, the processor circuitry 1252 and/or acceleration circuitry 1264 may be, or may include, an AI engine chip that can run many different kinds of AI instruction sets once loaded with the appropriate weightings and training code. Additionally or alternatively, the processor circuitry 1252 and/or acceleration circuitry 1264 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1252 and/or acceleration circuitry 1264 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 1270 provided by Huawei®, and/or the like. In some hardware-based implementations, individual subsystems of system 1250 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1250 also includes system memory 1254. Any number of memory devices may be used to provide for a given amount of system memory. As examples, the memory 1254 may be, or include, volatile memory such as random-access memory (RAM), static RAM (SRAM), dynamic RAM (DRAM), synchronous DRAM (SDRAM), RAMBUS® Dynamic Random-Access Memory (RDRAM®), and/or any other desired type of volatile memory device. Additionally or alternatively, the memory 1254 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1254 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1258 provides persistent storage of information such as data, applications, operating systems and so forth. In an example, the storage 1258 may be implemented via a solid-state disk drive (SSDD) and/or high-speed electrically erasable memory (commonly referred to as “flash memory”). Other devices that may be used for the storage 1258 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random-access memory (FeTRAM), anti-ferroelectric memory, magnetoresistive random-access memory (MRAM) memory that incorporates memristor technology, phase change RAM (PRAM), resistive memory including the metal oxide base, the oxygen vacancy base and the conductive bridge Random-Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1254 and/or storage circuitry 1258 may also incorporate three-dimensional (3D) cross-point (XPOINT) memories from Intel® and Micron®.

The memory circuitry 1254 and/or storage circuitry 1258 is/are configured to store computational logic 1283 in the form of software, firmware, microcode, or hardware-level instructions to implement the techniques described herein. The computational logic 1283 may be employed to store working copies and/or permanent copies of programming instructions, or data to create the programming instructions, for the operation of various components of system 1250 (e.g., drivers, libraries, application programming interfaces (APIs), etc.), an operating system of system 1250, one or more applications, and/or for carrying out the embodiments discussed herein. The computational logic 1283 may be stored or loaded into memory circuitry 1254 as instructions 1282, or data to create the instructions 1282, which are then accessed for execution by the processor circuitry 1252 to carry out the functions described herein. The processor circuitry 1252 and/or the acceleration circuitry 1264 accesses the memory circuitry 1254 and/or the storage circuitry 1258 over the interconnect (IX) 1256. The instructions 1282 direct the processor circuitry 1252 to perform a specific sequence or flow of actions, for example, as described with respect to flowchart(s) and block diagram(s) of operations and functionality depicted previously. The various elements may be implemented by assembler instructions supported by processor circuitry 1252 or high-level languages that may be compiled into instructions 1288, or data to create the instructions 1288, to be executed by the processor circuitry 1252. The permanent copy of the programming instructions may be placed into persistent storage devices of storage circuitry 1258 in the factory or in the field through, for example, a distribution medium (not shown), through a communication interface (e.g., from a distribution server (not shown)), over-the-air (OTA), or any combination thereof.

The IX 1256 couples the processor 1252 to communication circuitry 1266 for communications with other devices, such as a remote server (not shown) and the like. The communication circuitry 1266 is a hardware element, or collection of hardware elements, used to communicate over one or more networks 1263 and/or with other devices. In one example, communication circuitry 1266 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1266 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1256 also couples the processor 1252 to interface circuitry 1270 that is used to connect system 1250 with one or more external devices 1272. The external devices 1272 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1250, which are referred to as input circuitry 1286 and output circuitry 1284. The input circuitry 1286 and output circuitry 1284 include one or more user interfaces designed to enable user interaction with the platform 1250 and/or peripheral component interfaces designed to enable peripheral component interaction with the platform 1250. Input circuitry 1286 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1284 may be included to show information or otherwise convey information, such as sensor readings, actuator position(s), or other like information. Data and/or graphics may be displayed on one or more user interface components of the output circuitry 1284. Output circuitry 1284 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1250. The output circuitry 1284 may also include speakers and/or other audio emitting devices, printer(s), and/or the like. Additionally or alternatively, sensor(s) may be used as the input circuitry 1284 (e.g., an image capture device, motion capture device, or the like) and one or more actuators may be used as the output device circuitry 1284 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1250 may communicate over the IX 1256. The IX 1256 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1256 may be a proprietary bus, for example, used in a SoC based system.

The number, capability, and/or capacity of the elements of system 1250 may vary, depending on whether computing system 1250 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1250 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random-access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a p-type transistor layer comprising p-type transistors;
an n-type transistor layer comprising n-type transistors, wherein the n-type transistor layer is above the p-type transistor layer; and
one or more intermediate metal layers between the p-type transistor layer and the n-type transistor layer, wherein the one or more intermediate metal layers are coupled to the p-type transistor layer and to the n-type transistor layer.

2. The apparatus of claim 1, wherein:
the p-type transistors and the n-type transistors are in a static random-access memory (SRAM) cell;
the SRAM cell comprises a node coupled to a bit line via an access transistor; and
the one or more intermediate metal layers are coupled to the node.

3. The apparatus of claim 2, wherein:
the node is a first node;
the access transistor is a first access transistor;
the SRAM cell comprise a second node coupled to a complementary bit line via a second access transistor; and
the one or more intermediate metal layers are coupled to the second node.

4. The apparatus of claim 3, wherein the one or more intermediate metal layers are coupled to the first node in a first p-type transistor region of the p-type transistor layer, and to the second node in a second p-type transistor region of the p-type transistor layer.

5. The apparatus of claim 2, further comprising a top metal layer coupled to the bit line, wherein the top metal layer is above the one or more intermediate metal layers.

6. The apparatus of claim 1, wherein:
the p-type transistors and the n-type transistors are in a static random-access memory (SRAM) cell;
the SRAM cell comprises an inverter;
the inverter comprises an n-type transistor having a drain coupled to a drain of a p-type transistor, and a source coupled to a ground; and
the one or more intermediate metal layers are coupled to the ground.

7. The apparatus of claim 6, further comprising a bottom metal layer coupled to a source of the p-type transistor of the inverter.

8. The apparatus of claim 1, wherein:
the p-type transistors and the n-type transistors are in a static random-access memory (SRAM) cell;
the SRAM cell comprises a first inverter having a first n-type transistor and a first p-type transistor in series, and a second inverter having a second n-type transistor and a second p-type transistor in series; and
the one or more intermediate metal layers are coupled to a drain of the first p-type transistor and to a control gate of the second p-type transistor.

9. The apparatus of claim 1, wherein:
the p-type transistors and the n-type transistors are in a static random-access memory (SRAM) cell;
the SRAM cell comprises a first inverter having a first n-type transistor and a first p-type transistor in series, and a second inverter having a second n-type transistor and a second p-type transistor in series; and
the one or more intermediate metal layers are coupled to a control gate of the first p-type transistor and to a drain of the second p-type transistor.

10. The apparatus of claim 1, wherein:
the p-type transistors and the n-type transistors are in a static random-access memory (SRAM) cell;
the SRAM cell comprise a node coupled to a bit line via an access transistor and a word line coupled to a control gate of the access transistor; and
the one or more intermediate metal layers are coupled to the word line.

11. The apparatus of claim 1, wherein:
the p-type transistor layer comprises two p-type transistors in a six-transistor static random-access memory (SRAM) cell; and
the n-type transistor layer comprises four n-type transistors in the six-transistor SRAM cell.

12. The apparatus of claim 1, wherein:
the p-type transistor layer comprises four p-type transistors in an eight-transistor static random-access memory (SRAM) cell; and
the n-type transistor layer comprises four n-type transistors in the eight-transistor SRAM cell.

13. The apparatus of claim 1, wherein:
the p-type transistors comprise p-type metal-oxide-semiconductor field-effect transistor (MOSFETs) and the n-type transistors comprise n-type MOSFETs.

14. The apparatus of claim 1, wherein:
the one or more intermediate metal layers comprise a first intermediate metal layer having tracks extending in a first direction and a second intermediate metal layers comprising tracks extending in a second direction, perpendicular to the first direction.

15. The apparatus of claim 1, further comprising a complementary field-effect transistor (CFET) device which includes the p-type transistor layer, the n-type transistor layer and the one or more intermediate metal layers, wherein the CFET device is provided in at least one of an integrated circuit, a System on Chip, a System in Package or a computing device.

16. A complementary field-effect transistor (CFET) device, comprising:
one or more bottom metal layers;
a p-type transistor layer above the one or more bottom metal layers;
one or more intermediate metal layers above the p-type transistor layer;
an n-type transistor layer above the one or more intermediate metal layers; and
one or more top metal layers above the n-type transistor layer, wherein:
the one or more bottom metal layers are coupled to the p-type transistor layer;
the one or more intermediate metal layers are coupled to the p-type transistor layer and to the n-type transistor layer; and
the one or more top metal layers are coupled to the n-type transistor layer.

17. The CFET device of claim 16, wherein:
the p-type transistor layer comprises a plurality of p-type metal-oxide-semiconductor field-effect transistor (MOSFETs); and
the n-type transistor layer comprises a plurality of n-type MOSFETs.

18. The CFET device of claim 17, wherein:
the CFET device comprises a six-transistor static random-access memory (SRAM) cell including two of the p-type MOSFETs in the p-type transistor layer and four of the n-type MOSFETs in the n-type transistor layer.

19. The CFET device of claim 17, wherein:
the CFET device comprises an eight-transistor static random-access memory (SRAM) cell including four of the p-type MOSFETs in the p-type transistor layer and four of the n-type MOSFETs in the n-type transistor layer.

20. The CFET device of claim 17, wherein:
the one or more intermediate metal layers comprise a track coupled to a drain of one p-type MOSFET of the plurality of p-type MOSFETs and to a control gate of another p-type MOSFET of the plurality of p-type MOSFETs.
